(19) United States
(12) Patent Application Publication
(10) Pub. No.: US 2025/0345884 A1
(43) Pub. Date: Nov. 13, 2025

(54) HYBRID LASER SYSTEM AND METHOD FOR DRYING BATTERY ELECTRODE COATING

(71) Applicant: Coherent, Inc., Santa Clara, CA (US)

(72) Inventors: Majid ABBASI, Houston, TX (US); Timothy MCCOMB, Orlando, FL (US)

(73) Assignee: Coherent, Inc., Santa Clara, CA (US)

(21) Appl. No.: 18/660,536

(22) Filed: May 10, 2024

(51) Int. Cl. B23K 26/352; B23K 26/70; G02B 27/09; H01M 4/04; H01M 4/139; H01S 5/02251; H01S 5/40; H01S 5/42

(52) U.S. Cl. CPC B23K 26/352; B23K 26/704; G02B 27/0927; H01M 4/04; H01M 4/139; H01S 5/02251; H01S 5/4031; H01S 5/423

(57) ABSTRACT

A system for drying a battery electrode coating includes two laser diode arrays and a laser module. Each laser diode array emits multi-beam laser radiation to an edge region including a respective edge of a coating lane deposited on a metal foil. The laser module emits a diverging laser beam to an interior area of the coating lane between the two edges. The intensity distribution of the diverging laser beam at the coating lane spans a gap in the widthwise dimension between respective intensity distributions of the multi-beam laser radiation from the two laser diode arrays. The use of laser diode arrays to perform the edge drying allows for tailoring the intensity distribution of the combined laser irradiation to dry the coating lane without over-drying and delaminating the edges. The use of a single, diverging laser beam in the interior area allows for optimizing affordability and energy efficiency.

### TECHNICAL FIELD OF THE INVENTION

The present invention relates generally to the manufacture of electrochemical batteries, such as lithium-ion batteries and sodium-ion batteries. More particularly, the present invention relates to processes for laser drying the active coatings on the battery electrodes in an energy-efficient and even manner.

### DISCUSSION OF BACKGROUND ART

Electrochemical batteries such as lithium-ion batteries are, in large part due to their high energy density, the preferred power source in many different applications ranging from small portable electronic devices to electric vehicles. The basic unit of a such a battery cell consists of an anode, a cathode, and a separator therebetween. Each of the anode and cathode is a metal foil coated with an active material. The active material is the component that participates in the electrochemical reactions within the battery. In order to achieve the highest possible energy density, the metal foil is usually quite thin, for example less than 30 micrometers (m). The active material of the cathode is predominantly an oxide containing mobile ions, for example lithium or sodium, whereas the active material of the anode typically consists primarily of carbon forms, for example graphite and/or silicon.

For both the cathode and the anode, the active material is coated on the metal foils in the form of a slurry. In a typical manufacturing line, a large coil of metal foil is provided on a reel. The metal foil is transferred from this initial reel to another reel via a coating apparatus. The coating apparatus forms one or more coating “lanes” along the length of the metal foil. The slurry deposited by the coating apparatus is a mixture of the active material, a binder that helps adhere the active material to the metal foil, and a solvent used to ensure that the active material and binder can be evenly mixed and applied to the metallic foil. The coating apparatus subjects the slurry to a drying process that removes the solvent. This drying process is conventionally carried out using convection ovens or infrared-lamp drying. While convection ovens are widely used for this purpose, they are physically large and consume a large amount of energy. Infrared lamps provide a more compact solution as well as some improvement in terms of energy efficiency. Yet, the conventional drying process is still one of the most energy consuming parts of electrochemical battery production.

### SUMMARY OF THE INVENTION

Laser drying is as an alternative to conventional drying of battery electrode coatings using convection ovens or infrared lamp drying. Laser drying can be significantly more efficient than drying in convection ovens and even infrared lamp drying, especially when using high-efficiency laser sources. Laser drying of battery electrode coatings can be performed with an energy consumption level that is only between about 10% and 50% of the energy consumption of convection oven and infrared lamp drying.

However, the use of lasers for drying battery electrode coatings presents its own set of challenges. One such challenge is the potential for excess heating at the edges of the coating areas. The bare metal foil adjacent to the coating edges can heat up rapidly when irradiated with laser light, thereby accelerating the heating and drying of the coating edges. Additionally, the coating edges tend to be thinner than interior areas of the coating and thus dry quicker than the interior areas when subjected to the same amount of heat. Excess heating of the coating edges can lead to over-drying and delamination of the coating from the metal foil.

Disclosed herein are hybrid laser drying systems, and associated methods, capable of tailoring the spatial intensity distribution of the laser light to evenly dry one or more coating lanes on a metal foil, so as to ensure complete drying while preventing excess heating of the coating edges. The disclosed hybrid laser drying systems and methods are suitable for drying the active-material coating on battery electrodes, such as the anode and cathode of a lithium-ion or sodium-ion battery. In the presently disclosed systems and methods, a diverging laser beam dries the interior area of a coating lane, while each coating edge is dried by the multi-beam output of a laser diode array. The use of a laser diode array to dry each coating edge allows for electronically adjusting the laser intensity distribution at the coating edge. For optimal energy efficiency of the coating edge drying process and optimal spatial control of the laser intensity distribution, the laser diode array may be a vertical cavity surface emitting laser (VCSEL) array. In the interior area of the coating, where relatively uniform laser irradiation is acceptable, the more affordable and potentially more energy efficient solution of a diverging laser beam suffices. In most scenarios, the interior area represents the majority of the total coating area. In one example, the interior area of the coating is dried by a fiber-coupled diode laser with a spatially homogenized output.

In one aspect of the invention, a system for drying a battery electrode coating includes two laser diode arrays and a laser module. Each of the two laser diode arrays is arranged to emit multi-beam laser radiation to a respective edge region including a respective one of two edges of a coating lane deposited on a metal foil. At least portions of each laser diode array are controllable separately from other portions of the same laser diode array such that a respective intensity distribution of the multi-beam radiation from each laser diode array is adjustable. The laser module is configured to emit a diverging laser beam from an output port, disposed between the two laser diode arrays with respect to a widthwise dimension of the metal foil, to an interior area of the coating lane between the two edges. An intensity distribution of the diverging laser beam at the coating lane spans a gap in the widthwise dimension between the respective intensity distributions of the multi-beam laser radiation from the two laser diode arrays.

In another aspect of the invention, a method for drying a battery electrode coating includes steps of, for each of one or more coating lanes deposited on a metal foil, (a) emitting multi-beam laser radiation from each of two laser diode arrays to an edge region including a respective one of two edges of the coating lane, (b) emitting a diverging laser beam from an output port to an interior area of the coating lane between the two edges, and (c) transporting the metal foil through a region irradiated by the diverging laser beam and the multi-beam laser radiation from each laser diode array. An intensity distribution, with respect to a widthwise dimension of the metal foil, of the diverging laser beam at the coating lane spans a gap between respective intensity distributions of the multi-beam laser radiation from the two laser diode arrays. An average intensity of the diverging laser beam in the interior area exceeds an average intensity of the multi-beam laser radiation from each laser diode array in the corresponding edge region.

### BRIEF DESCRIPTION OF THE DRAWINGS

The accompanying drawings, which are incorporated in and constitute a part of the specification, schematically illustrate preferred embodiments of the present invention, and together with the general description given above and the detailed description of the preferred embodiments given below, serve to explain principles of the present invention.

FIG. 1 illustrates a coating apparatus for coating a metal foil, according to an embodiment. The coating apparatus uses a hybrid laser system to laser dry the deposited coating material without overheating the coating material proximate edges thereof.

FIG. 2 shows an embodiment of the hybrid laser system of FIG. 1 in further detail.

FIG. 3 shows an exemplary cross-sectional profile of the metal foil and a coating lane together with an exemplary widthwise intensity distribution of the combined laser radiation from the hybrid laser system of FIG. 1. These cross-sectional profiles are overlayed on a cross-sectional view of the parts of the hybrid laser system as positioned above the metal foil, according to an embodiment.

FIG. 4 illustrates a laser module that includes a fiber-coupled laser with a homogenized output and may be implemented in the hybrid laser system of FIG. 1, according to an embodiment.

FIG. 5 illustrates a hybrid laser system for laser drying two parallel coating lanes on the same metal foil, according to an embodiment.

FIG. 6 is a flowchart for a method for laser drying a battery electrode coating, according to an embodiment. This method utilizes laser diode arrays to dry edges of a coating lane on a metal foil, thereby enabling shaping of the laser intensity distribution to prevent over-drying and delamination of the edges of the coating.

### DETAILED DESCRIPTION OF THE INVENTION

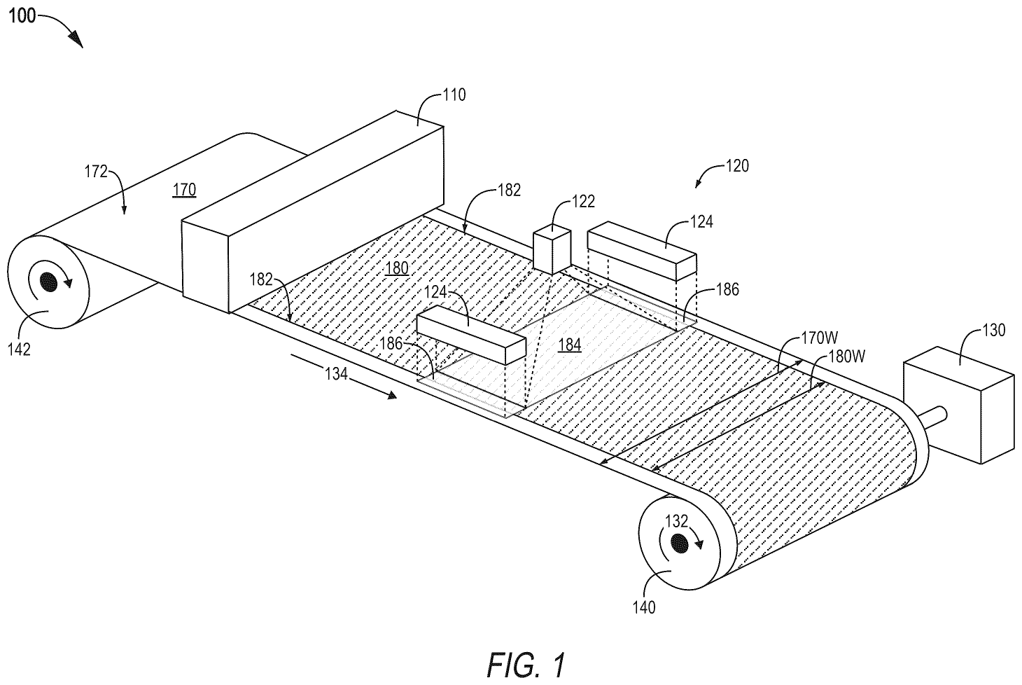

Referring now to the drawings, wherein like components are designated by like numerals, FIG. 1 illustrates one coating apparatus 100 for coating a metal foil 170. Coating apparatus 100 uses a hybrid laser system 120 to laser dry the deposited coating material without overheating the coating material disposed along edges 182 thereof. Coating apparatus 100 may be used in the manufacture of battery electrodes, e.g., electrodes for lithium-ion or sodium-ion batteries. Once coated by coating apparatus 100, metal foil 170 may be cut to form a plurality (e.g., a large number) of coated battery electrodes. Depending on the composition of the coating and the type of metal chosen for metal foil 170, the coated metal foil may function as an anode or a cathode. Coating apparatus 100 includes a coating applicator 110, a hybrid laser system 120, and a transport system 130.

Transport system 130 drives metal foil 170 along a travel direction 134, allowing metal foil 170 to pass beneath coating applicator 110 and hybrid laser system 120. In the depicted implementation, transport system 130 pulls metal foil 170 from a feeding reel 142 to a receiving reel 140 by rotating receiving reel 140 as indicated by rotation direction 132. Alternatively, transport system 130 may utilize other techniques for transporting metal foil 170 beneath coating applicator 110 and hybrid laser system 120, such as rubberized wheels.

Herein, the terms “beneath” and “above” do not necessarily imply a particular positioning in relation to the direction of gravity. However, depending on the viscosity of the deposited coating material, it may be beneficial to keep the coated surface of metal foil 170 facing up, against the direction of gravity, to prevent the deposited coating material from running and/or detaching from metal foil 170 before the laser drying process is complete.

As metal foil 170 passes beneath coating applicator 110, coating applicator 110 deposits coating material on a surface 172 of metal foil 170 to form a coating lane 180 thereon. Until dried, the material of coating lane 180 may be in the form of a slurry. As deposited, the material of coating lane 180 may include an active material, a binder, and a solvent. In one example, suitable for the manufacture of lithium-ion battery cathodes, metal foil 170 is an aluminum foil, and the material of coating lane 180 includes a lithium oxide. For the manufacture of a lithium-ion battery anodes, metal foil 170 may be made of copper, a copper alloy, or nickel, and the material of coating lane 180 may include graphite and/or silicon.

The width 180W of coating lane 180 is less than the width 170W of metal foil 170, such that there are bare portions of metal foil 170 next to edges 182. In a typical scenario, coating lane 180 is thinner along edges 182 than elsewhere. In the interior region, away from edges 182, the thickness of coating lane 180 may be substantially uniform.

Hybrid laser system 120 is positioned downstream from coating applicator 110 and laser beams dry coating lane 180 as it passes beneath hybrid laser system 120. This drying process may entail evaporating a solvent included in the deposited coating material. Hybrid laser system 120 includes a laser module 122 and two laser diode arrays 124.

Laser module 122 includes a laser source and an output port that emits laser radiation generated by the laser source. The output port of laser module 122 is situated between laser diode arrays 124, with respect to the widthwise dimension of metal foil 170. The widthwise dimension of metal foil 170 is in the plane of metal foil 170 and orthogonal to travel direction 134, whereas the lengthwise dimension of metal foil 170 is parallel to travel direction 134. Laser module 122 emits a diverging laser beam that irradiates an interior area 184 of coating lane 180. Interior area 184 is between the two opposite edges 182 and does not extend all the way to either one of edges 182. The diverging laser beam emitted by laser module 122 may be a single laser beam. The laser radiation emitted by each laser diode array 124, on the other hand, is composed of a plurality of laser beams. In a typical scenario, the laser radiation emitted by each laser diode array 124 includes one laser beam from each laser diode of the array. In some scenarios, however, not all laser diodes of each laser diode array 124 are active. Each laser diode array 124 serves to dry a portion of coating lane 180 along a respective one of edges 182. More specifically, each laser diode array 124 is positioned to irradiate a region 186 of metal foil 170 that includes one of coating edges 182.

In the widthwise dimension of metal foil 170, the intensity distribution of the diverging laser beam from laser module 122 at metal foil 170 may span the gap between the respective intensity distributions of the multi-beam laser radiation from the two laser diode arrays 124 at metal foil 170. The combined intensity distribution of laser radiation emitted by laser module 122 and the two laser diode arrays 124 may span the entire width 170W of metal foil 170.

Laser module 122 may irradiate interior area 184 with relatively uniform intensity. In most cases, however, the laser intensity required to dry interior area 184 exceeds the laser intensity suitable for drying the portions of coating lane 180 close to edges 182. Coating lane 180 is commonly thicker than metal foil 170 by up to about an order of magnitude, and the material of coating lane 180 heats relatively slowly due to both its thickness and evaporation of the liquid solvent. In contrast, the bare portions of metal foil 170, located adjacent edges 182, tend to heat up quickly when irradiated, resulting in accelerated heating of the portions of coating lane 180 close to edges 182. Additionally, while the interior region of coating lane 180 away from edges 182 may be substantially uniform, coating lane 180 is usually thinner along edges 182. For this reason alone, the portions of coating lane 180 close to edges 182 may require less laser intensity to dry than interior area 184. The reduced thickness of coating lane 180 along edges 182, and the proximity of edges 182 to bare portions of metal foil 170, render the portions of coating lane 180 along edges 182 susceptible to overheating and, thus, delamination if irradiated as intensely as the interior area 184.

Hybrid laser system 120 prevents over-drying of coating lane 180 near edges 182 by using a separate dedicated laser source, namely laser diode array 124, to dry coating lane 180 along each edge 182. Each laser diode array 124 may irradiate the corresponding edge region 186 with less intense laser radiation than used in interior area 184. Furthermore, each laser diode array 124 may be operated such that the multi-beam laser radiation emitted therefrom is spatially nonuniform, particularly in the widthwise dimension. Thus, by virtue of laser diode arrays 124, hybrid laser system 120 is capable of shaping the intensity distribution in edge regions 186 to optimally dry the portion of coating lane 180 near edges 182 while avoiding over-drying and delamination. For example, laser diode arrays 124 may be operated such that the laser intensity in the bare portions of metal foil 170 adjacent to edges 182 is at most 20% of the laser intensity at the center of coating lane 180. In interior area 184, where such shaping of the intensity distribution is typically not needed, laser module 122 may utilize a simpler, more affordable, and potentially also more efficient laser source.

While FIG. 1 shows hybrid laser system 120 implemented in coating apparatus 100 together with coating applicator 110 and transport system 130, hybrid laser system 120 may instead be provided as a standalone system that can be implemented as needed to dry a coating lane on a metal foil. For example, such a standalone hybrid laser system 120 may replace (or augment) a conventional drying system (e.g., a convection oven or an infrared lamp) in an existing coating apparatus.

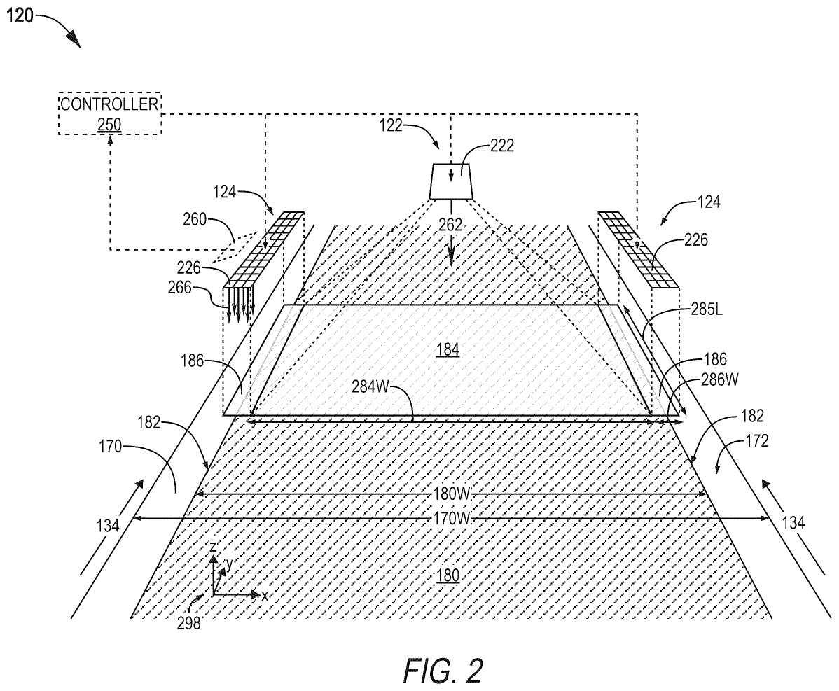

FIG. 2 is a perspective view showing hybrid laser system 120 in further detail. In this perspective view, metal foil 170 is in the xy-plane of a cartesian coordinate system 298, and travel direction 134 is in the positive y-direction. An output port 222 of laser module 122 is disposed above metal foil 170 and emits a diverging laser beam 262 that irradiates interior area 184. An actual laser source of laser module 122 (not shown in FIG. 2) may be disposed at output port 222 or remotely therefrom. Laser module 122 may shape diverging laser beam 262 to irradiate interior area 184 with relatively uniform intensity. Each laser diode array 124 includes a plurality of laser diodes 226, each operable to emit a corresponding laser beam 266. The collection of laser beams 266 from each laser diode array 124 irradiates a corresponding edge region 186. The wavelength(s) of diverging laser beam 262 and laser beams 266 may be in the range between 200 and 2000 nanometers.

Each laser diode array 124 may include any type of laser diodes, for example, surface-emitting laser diodes, edge-emitting laser diodes, diode bars, or a combination thereof. The surface-emitting laser diodes may be single- or multi-junction VCSELs, or photonic crystal surface emitting lasers (PCSELs). In one embodiment, each laser diode array 124 is a VCSEL array. The VCSEL array may be advantageous for at least these reasons: VCSELs can achieve high electrical-to-optical efficiency, VCSELs can be packed tightly in the array, and the output beam from a VCSEL can be more directional than the output beam from an edge-emitting laser diode. Tight packaging of laser diodes 226 combined with high directionality of each individual laser beam 266 minimizes the spatial overlap between laser beams 266 from the same laser diode array 124, which in turn enables fine spatial control of the intensity distribution of the multi-beam laser radiation from each laser diode array 124.

In the depicted embodiment, each laser diode array 124 is a two-dimensional laser diode array with the laser diodes thereof arranged in orthogonal rows and columns. In an alternative embodiment, each laser diode array 124 is a one-dimensional array oriented along the widthwise dimension (i.e., oriented parallel to the x-axis of coordinate system 298). However, achieving the heating required to dry coating lane 180 along edges 182 may necessitate using a two-dimensional laser diode array that extends also in the lengthwise dimension (i.e., in the dimension parallel to the y-axis of coordinate system 298). The number of laser diodes 226 in each laser diode array 124 may be between three and thousands. For example, embodiments of laser diode array 124 based on edge-emitting laser diodes may include up to about a hundred laser diodes, while embodiments of laser diode array 124 based on VCSELs may include between a hundred and several thousand laser diodes.

Hybrid laser system 120 may include a controller 250, comprising one or more processors configured to execute code stored in memory, wherein the code comprises instructions for controlling the systems and performing the methods described herein. Controller 250 controls each laser diode array 124 to adjust the intensity distribution of the emitted multi-beam laser radiation. In one embodiment, each laser diode 226 is individually controllable, providing the maximum spatial resolution for adjusting the intensity distribution of the emitted laser radiation. In another embodiment, where the maximum spatial resolution is not required, each laser diode array 124 is segmented into a plurality of sub-arrays. Each sub-array is individually controllable, but the individual laser diodes 226 within each sub-array are operated together. In one example of this embodiment, each laser diode array 124 is a two-dimensional array containing a plurality of laser diode columns oriented lengthwise. These laser diode columns are individually controllable, but individual laser diodes 226 within a given laser diode column cannot be controlled separately from the other laser diodes 226 in the same laser diode column. This example still allows for shaping the intensity distribution of the laser radiation, emitted by each laser diode array 124, in the widthwise dimension, which may be sufficient to prevent over-drying of the coating material close to edges 182.

Controller 250 may also control emission of diverging laser beam 262 from output port 222 of laser module 122. Certain embodiments of hybrid laser system 120 include one or more sensors 260 that monitor coating lane 180 and/or metal foil 170. For example, a sensor 260 may be positioned to monitor one edge region 186 as depicted in FIG. 2, and a similar sensor 260 (not depicted) may be positioned to monitor the other edge region 186. Each sensor 260 may monitor a temperature of coating lane 180 and/or metal foil 170, in which case each sensor 260 may include a thermopile or a thermal camera. Controller 250 may control each laser diode array 124, and optionally also laser module 122, based on data obtained by sensor(s) 260. Such feedback enables real-time adjustments of laser radiation from hybrid laser system 120 to prevent over-drying of the coating material close to edges 182. This is particularly advantageous in scenarios where the thickness of coating lane 180 varies in the lengthwise dimension of metal foil 170. Sensor(s) 260 may also be a camera configured to visually monitor the drying process.

Each edge region 186 includes a corresponding edge 182 of coating lane 180. The width 286W of each edge region 186 may span beyond the corresponding edge 182, as depicted in FIG. 2. Alternatively, one or both of edge regions 186 is entirely within coating lane 180 and terminates at the corresponding edge 182. Typically, to ensure complete drying of coating lane 180, the width 284W of interior area 184 spans the gap between edge regions 186. In the depicted embodiment, interior area 184 and edge regions 186 have a length 285L. Without departing from the scope hereof, length 285L of edge regions 186 may differ from length 285L of interior area 184. In one scenario, width 180W of coating lane 180 is in the range between 5 and 200 centimeters (cm), width 170W of metal foil 170 extends at least 2 cm beyond each edge 182, and width 286W of each edge region 186 extends into coating lane 180 by between 1 and 5 cm and outside coating lane 180 by at least 1 cm. In the widthwise dimension, interior area 184 may be centered on coating lane 180, and coating lane 180 may be centered on metal foil 170. Length 285L is, for example, between 50% and 1000% of width 180W. Without departing from the scope hereof, a small fraction of diverging laser beam 262 may spill into one or both of edge region 186. In addition, interior area 184 and edge regions 186 may not be perfectly rectangular in shape. For example, the corners of interior area 184 may be rounded.

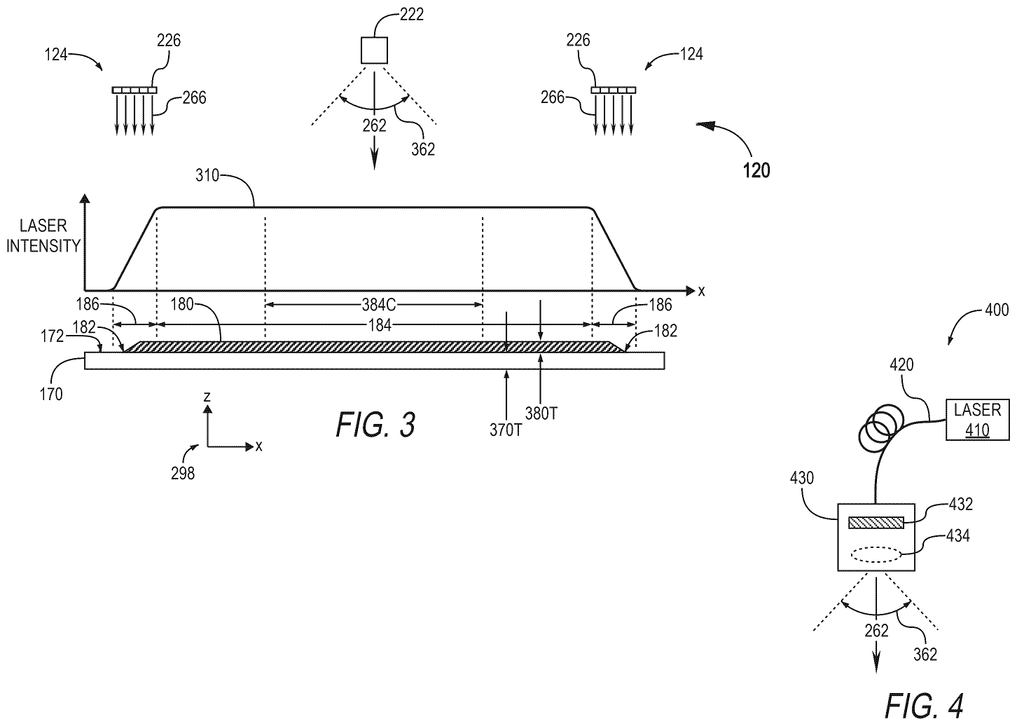

FIG. 3 is a diagram showing an exemplary cross-sectional profile of metal foil 170 and coating lane 180, together with an exemplary widthwise intensity distribution 310 of the combined laser radiation from hybrid laser system 120 at the surface of metal foil 170 and coating lane 180. The FIG. 3 diagram overlays intensity distribution 310 on a cross-sectional view of output port 222 of laser module 122 and laser diode arrays 124 as positioned above metal foil 170. The depicted cross section is parallel to the xz-plane of coordinate system 298 (see FIG. 2).

The thickness 380T of coating lane 180 may be substantially uniform except near edges 182 where thickness 380T tapers to zero. Apart from near edges 182, thickness 380T may be in the range between 50 and 500 m. For comparison, the thickness 370T of metal foil 170 may be less than 50 m or even less than 20 m.

In the depicted example, diverging laser beam 262 has a divergence angle 362, in the widthwise dimension, that is sized to span the width of interior area 184. Intensity distribution 310 is uniform within interior area 184. Laser diode arrays 124 are controlled such that the intensity distribution 310 tapers to zero through edge regions 186.

In a more general example, the laser intensity within interior area 184, or at least an average of this laser intensity, exceeds the laser intensity in edge regions 186, and the intensity distribution may be relatively uniform within interior area 184. For example, within a central half 384C of the width of interior area 184, the laser intensity may be uniform to within 20%, or even to within 10% or better. In each edge region 186, the intensity distribution may exhibit a gradient, such that the laser intensity generally decreases as a function of distance away from the center of coating lane 180. The gradient is not necessarily constant. Each laser diode array 124 may be adjusted such that the laser intensity at edges 182 is at most 20% of average laser intensity within central half 384C.

FIG. 4 illustrates one laser module 400 that includes a fiber-coupled laser with a homogenized output and may be implemented in hybrid laser system 120 to generate and emit diverging laser beam 262 so as to irradiate interior area 184 of coating lane 180. Laser module 400 includes a laser 410, an optical fiber 420, and an output port 430. Laser 410 generates laser radiation that is coupled to output port 430 via optical fiber 420. Output port 430 is an embodiment of output port 222 that includes a homogenizer 432. Homogenizer 432 flattens the intensity distribution of diverging laser beam 262 to achieve a desired uniformity of the laser intensity within interior area 184. Homogenizer 432 may include an optical fiber, a diffractive beam-shaping element, a prism array, a lens array, and/or a light pipe to homogenize laser radiation received from laser 410. Output port 430 may also include an objective 434, containing one or more lenses, that sizes divergence angle 362 as needed.

In one embodiment, laser 410 is a solid-state laser, for example a diode laser. In order to sufficiently heat interior area 184, laser 410 is typically more powerful than any single laser diode 226 of laser diode arrays 224 by several orders of magnitude. At least when laser 410 is a diode laser, diverging laser beam 262 may irradiate interior area 184 at a lower cost than, e.g., a large laser diode array, in terms of both hardware and energy cost.

In some scenarios, two or more parallel coating lanes are to be produced on the same metal foil. The concepts of hybrid laser system 120 are readily applicable to laser drying of such parallel coating lanes.

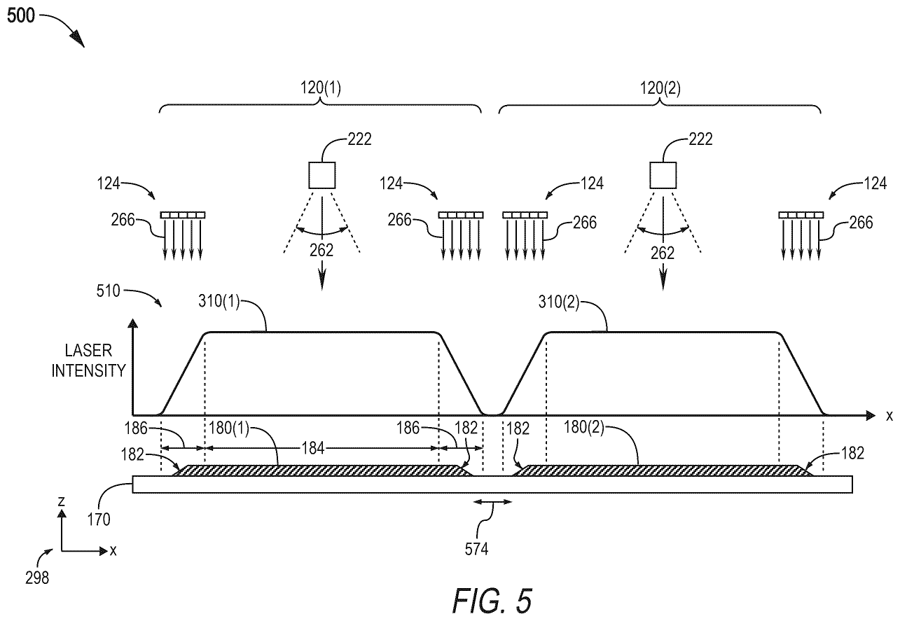

FIG. 5 illustrates one hybrid laser system 500 for laser drying two parallel coating lanes 180 on metal foil 170. FIG. 5 shows hybrid laser system 500 in a cross-sectional view similar to that used for hybrid laser system 120 in FIG. 3. Hybrid laser system 500 includes two instances of hybrid laser system 120, each positioned to laser dry a corresponding one of two coating lanes 180 as discussed above in reference to FIGS. 1-3. The two instances of hybrid laser system 120 may be positioned at the same location in the lengthwise dimension, i.e., in the travel direction of metal foil 170. Alternatively, if for example dictated by spatial constraints, the two instances of hybrid laser system 120 may be offset from each other in the lengthwise dimension.

FIG. 5 also depicts an exemplary combined intensity distribution 510 of the emitted laser radiation at the surface of metal foil 170 and coating lanes 180. In the depicted example, the distance 574 between the two coating lanes 180 is sufficiently large that the combined intensity distribution 510 consists of separate two lobes, one for each coating lane 180. Each lobe is identical to intensity distribution 310 discussed above in reference to FIG. 3 but may be generalized as also discussed above in reference to FIG. 3.

In another scenario, not depicted in FIG. 5, distance 574 between the two coating lanes 180 is sufficiently small that a single laser diode array 124 may be used to dry the portions of the two coating lanes 180 located along the two adjacent, inside edges 182. That is, a single laser diode array 124 may be used to dry coating material within a region that includes the right edge 182 of coating lane 180(1) and the left edge of coating lane 180(2) as depicted in FIG. 5. In a corresponding modification of hybrid laser system 500, the two laser diode arrays 124 arranged to dry the coating material along the two adjacent, inside edges 182 are replaced by a single laser diode array 124.

Hybrid laser system 500 is readily extendable to laser drying of three or more parallel coating lanes 180 on the same metal foil 170. Such extensions of hybrid laser system 500 may include a complete hybrid laser system 120 for each coating lane 180. In this case, the hybrid laser system includes a series of laser diode arrays 124 and output ports 222 arranged along the widthwise dimension such that (a) each pair of nearest-neighbor output ports 222 has a pair of laser diode arrays 124 therebetween and (b) the series starts and ends with a laser diode array 124. Alternatively, these extensions of hybrid laser system 500 may utilize a single laser diode array 124 to dry the coating material near each pair of adjacent edges 182. In this case, the hybrid laser system includes a series of laser diode arrays 124 and output ports 222 arranged along the widthwise dimension with only a single laser diode array 124 between each pair of nearest-neighbor output ports 222.

In hybrid laser system 500, and in any one of the discussed modifications and extensions, the plurality of output ports 222 may receive the to-be-emitted laser radiation from a respective plurality of laser sources. Alternatively, two or more output ports 222 may receive the to-be-emitted laser radiation from the same laser source. In one example, a single laser source generates the needed laser radiation for every output port 222.

Hybrid laser system 500, and any one of its modifications and extensions discussed above, may be implemented in corresponding modifications of coating apparatus 100 where coating applicator 110 deposits two, three, or more parallel coating lanes 180.

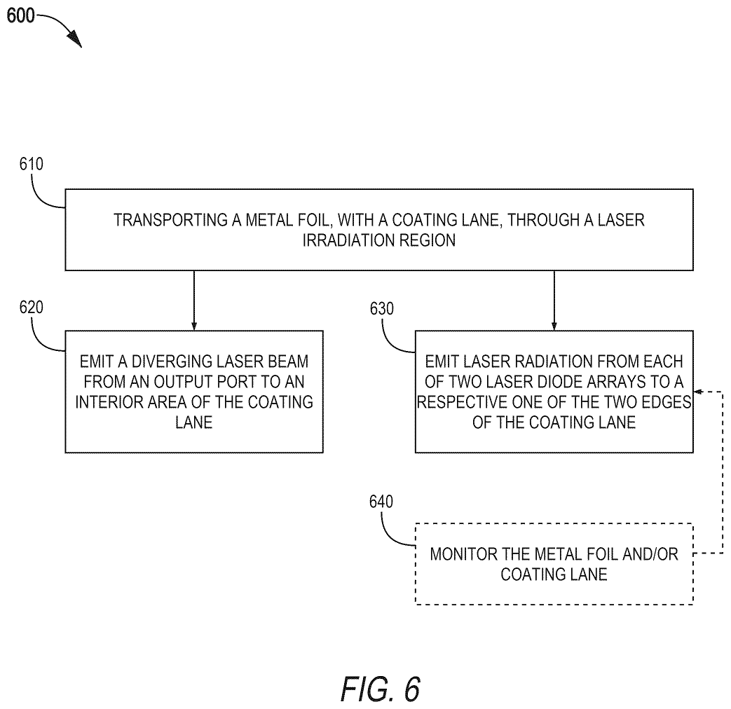

FIG. 6 is a flowchart for one method 600 for drying a battery electrode coating.

Method 600 transports a metal foil, with a coating lane, through a laser irradiation region (step 610). At the laser irradiation region, method 600 (a) emits a diverging laser beam from an output port to an interior area of the coating lane (step 620) and (b) emits laser radiation from each of two arrays of laser diodes to portions of the coating lane, and optionally the metal foil, near a respective one of two edges of the coating lane (step 630). The use of laser diode arrays to perform edge laser-drying step 630 enables shaping of the laser intensity distribution to prevent over-drying and delamination of the edges of the coating. In fact, edge laser-drying step 630 may entail separately controlling individual laser diodes or sub-arrays of each laser diode array to tailor the intensity distribution near the coating edges to prevent over-drying. In certain embodiments, edge laser-drying step 630 relies on feedback from a monitoring step 640 that monitors the metal foil and/or coating lane. Monitoring step 640 may thermally monitor the metal foil and/or coating lane.

Method 600 may be used to laser dry coating lane 180 on metal foil 170. In one example, transport step 610 is performed by transport system 130 as discussed above in reference to FIG. 1, while hybrid laser system 120 performs interior laser-drying step 620 and edge laser-drying step 630 as discussed above in reference to FIGS. 1-3. Optional monitoring step 640 may be performed by one or more sensors 260, as discussed above in reference to FIG. 2. Controller 250 may control the execution of edge laser-drying step 630, as discussed above in reference to FIG. 2, with or without feedback from sensor(s) 260 and monitoring step 640.

Method 600 is readily extendable to laser drying of two of more parallel coating lanes on the same metal foil, in a manner similar to that discussed above for hybrid laser system 500 in reference to FIG. 5.

The present invention is described above in terms of a preferred embodiment and other embodiments. The invention is not limited, however, to the embodiments described and depicted herein. Rather, the invention is limited only by the claims appended hereto.

What is claimed is:

1. A system for drying a battery electrode coating, comprising:
two laser diode arrays, each arranged to emit multi-beam laser radiation to a respective edge region including a respective one of two edges of a coating lane deposited on a metal foil, wherein at least portions of each laser diode array are controllable separately from other portions of the same laser diode array such that a respective intensity distribution of the multi-beam radiation from each laser diode array is adjustable; and
a laser module to emit a diverging laser beam from an output port, disposed between the two laser diode arrays with respect to a widthwise dimension of the metal foil, to an interior area of the coating lane between the two edges, an intensity distribution of the diverging laser beam at the coating lane spanning a gap in the widthwise dimension between the respective intensity distributions of the multi-beam laser radiation from the two laser diode arrays.

2. The system of claim 1, wherein a combined intensity distribution, in the widthwise dimension, of the diverging laser beam and the multi-beam laser radiation from each laser diode array spans across a width of the coating lane.

3. The system of claim 1, wherein the interior area includes neither one of the two edges.

4. The system of claim 1, wherein the laser module includes a laser to generate the diverging laser beam and an optical fiber to couple the diverging laser beam from the laser to the output port.

5. The system of claim 1, wherein the output port includes a homogenizer to flatten the intensity distribution of the diverging laser beam at the metal foil.

6. The system of claim 1, wherein the laser module includes at least one diode laser to generate the diverging laser beam.

7. The system of claim 1, wherein an average intensity of the diverging laser beam in the interior region exceeds an average intensity of the multi-beam laser radiation from each laser diode array in the corresponding edge region.

8. The system of claim 1, wherein each laser diode array includes a vertical-cavity surface-emitting laser diode array.

9. The system of claim 8, wherein the vertical-cavity surface-emitting laser diode array is a two-dimensional array.

10. The system of claim 1, wherein each laser diode array includes a plurality of edge emitting laser diodes or a plurality of diode bars.

11. The system of claim 1, wherein each laser diode array includes a series of separately controllable sub-arrays of laser diodes located at different distances from a center of the coating lane.

12. The system of claim 1, further comprising a controller communicatively coupled with the laser diode arrays to adjust the intensity distribution of the multi-beam laser radiation from each laser diode array.

13. The system of claim 12, wherein the controller is configured to set the intensity distribution of the multi-beam laser radiation from each laser diode array such that, in each edge region, a combined intensity distribution of the diverging laser beam and the multi-beam laser radiation from each laser diode array decreases in a widthwise direction away from a center of the coating lane.

14. The system of claim 12, further comprising one or more sensors configured to monitor the coating lane or the metal foil, the controller being communicatively coupled to each of the one or more sensors to adjust the intensity distribution of the multi-beam laser radiation from each laser diode array at least in part based on data obtained from the one or more sensors.

15. An apparatus for coating a battery electrode, comprising:
the system of claim 1;
a coating applicator to deposit the coating lane on the metal foil; and
a transport system to drive the metal foil along a lengthwise dimension thereof, parallel to the coating lane, so as to pass the metal foil by the applicator and through the diverging laser beam and the multi-beam laser radiation from each laser diode array.

16. The system of claim 1, configured to dry a plurality of separate, parallel coating lanes on the metal foil and further comprising:
at least one additional instance of the output port such that the system includes a series of output ports distributed along a widthwise dimension of the metal foil orthogonal to the coating lanes, each of the output ports being arranged to emit a corresponding diverging laser beam to the interior area a respective one of the coating lanes; and
at least one additional instance of the laser diode array forming along with the two laser diode arrays a set of laser diode arrays such that (a) each pair of output ports, adjacent to each other in the series, has one or two laser diode arrays of the set of laser diode arrays therebetween to dry edges of the corresponding coating lanes, and (b) the series of output ports is between two laser diode arrays, of the set of laser diode arrays, to dry outermost edges of the coating lanes.

17. A method for drying a battery electrode coating, comprising steps of, for each of one or more coating lanes deposited on a metal foil:
emitting multi-beam laser radiation from each of two laser diode arrays to an edge region including a respective one of two edges of the coating lane;
emitting a diverging laser beam from an output port to an interior area of the coating lane between the two edges; and
transporting the metal foil through a region irradiated by the diverging laser beam and the multi-beam laser radiation from each laser diode array;
wherein (a) an intensity distribution, with respect to a widthwise dimension of the metal foil, of the diverging laser beam at the coating lane spans a gap between respective intensity distributions of the multi-beam laser radiation from the two laser diode arrays at the coating lane, and (b) an average intensity of the diverging laser beam in the interior area exceeds an average intensity of the multi-beam laser radiation from each laser diode array in the corresponding edge region.

18. The method of claim 17, wherein the diverging laser beam dries the interior area of the coating lane, and further comprising a step of adjusting the intensity distribution of the multi-beam laser radiation from each laser diode array to dry the coating lane in the edge region without causing delamination.

19. The method of claim 17, wherein the intensity distribution of the multi-beam laser radiation from each laser diode array is spatially nonuniform in a widthwise dimension at the metal foil.

20. The method of claim 17, wherein a combined intensity distribution of the diverging laser beam and the multi-beam laser radiation from each laser diode array spans across a width of the coating lane.

21. The method of claim 17, wherein the intensity distribution of the multi-beam laser radiation from each laser diode array extends beyond the coating lane in the widthwise dimension.

22. The method of claim 17, further comprising generating the diverging laser beam with at least one diode laser.

23. The method of claim 22, further comprising fiber-coupling the diverging laser beam from the diode laser to the output port.

24. The method of claim 17, further comprising a step of monitoring each coating lane or the metal foil, the step of adjusting comprising adjusting the intensity distribution of the multi-beam laser radiation from each laser diode array at least in part based on data obtained in the step of monitoring.

25. The method of claim 17, wherein the intensity distribution of the diverging laser beam is uniform to within 20% at least within a central half of a width of the coating lane.

26. The method of claim 17, wherein, in each edge region, the combined intensity distribution decreases in direction away from a center of the coating lane.

27. The method of claim 17, wherein each laser diode array includes an array of surface-emitting laser diodes, an array of edge emitting laser diodes, or a plurality of diode bars.
